(19) United States
(12) Patent Application Publication
(10) Pub. No.: US 2025/0230037 A1
(43) Pub. Date: Jul. 17, 2025

(54) MICRO-ELECTRO-MECHANICAL SYSTEM PACKAGE AND FABRICATION METHOD THEREOF

(71) Applicant: Vanguard International Semiconductor Corporation, Hsinchu (TW)

(72) Inventors: ROHIT PULIKKAL KIZHAKKEYIL, Singapore (SG); RAKESH CHAND, Singapore (SG); RAMACHANDRAMURTHY PRADEEP YELEHANKA, Singapore (SG); GUOFU ZHOU, Singapore (SG)

(73) Assignee: Vanguard International Semiconductor Corporation, Hsinchu (TW)

(21) Appl. No.: 18/409,801

(22) Filed: Jan. 11, 2024

(51) Int. Cl. B81B 7/00; B81C 1/00

(52) U.S. Cl. CPC B81B 7/0077; B81C 1/00531; B81B 2201/0235; B81B 2201/0242; B81B 2203/0307; B81B 2203/0315; B81B 2207/07; B81C 2201/0132; B81C 2201/0147

(57) ABSTRACT

A MEMS package includes a wafer with an interconnect layer. A first device layer includes a first MEMS device having a first thickness, is disposed on the wafer and bonded to the interconnect layer. A second device layer includes a second MEMS device having a second thickness thinner than the first thickness, is laterally spaced apart from the first device layer, disposed on the wafer and bonded to the interconnect layer. A first cap substrate with a first cavity is bonded to the first device layer. The first MEMS device corresponds to the first cavity. A second cap substrate with a second cavity is laterally spaced apart from the first cap substrate and bonded to the second device layer. The second MEMS device corresponds to the second cavity.

### BACKGROUND OF THE INVENTION

### 1. Field of the Invention

The present disclosure relates generally to micro-electro-mechanical system (MEMS) packages, and more particularly to a MEMS package including MEMS devices with different device layer thicknesses, and fabrication methods thereof.

### 2. Description of the Prior Art

Micro-electro-mechanical system (MEMS) devices are microscopic devices that integrate mechanical and electrical components to sense physical quantities and/or to interact with the surrounding environment. MEMS devices, such as accelerometers, gyroscopes, pressure sensors and microphones, have found widespread use in many modern electronic products. For example, inertial measurement units (IMU) composed of accelerometers and/or gyroscopes are commonly used in tablet computers, automobiles, or smartphones. For some applications, various MEMS devices need to be integrated into one MEMS package. However, for MEMS devices requiring different device layer thicknesses, these MEMS devices need to be fabricated separately by using different device wafers to form device layers of different thicknesses and then co-packaged. Therefore, the whole fabricating process of the conventional MEMS packages is complicated, and the cost thereof is also increased.

### SUMMARY OF THE INVENTION

In view of this, the present disclosure provides micro-electro-mechanical system (MEMS) packages and fabrication methods thereof to overcome the drawbacks of the conventional MEMS packages. The MEMS package includes MEMS devices with different device layer thicknesses to meet the sensitivities and the performances of various MEMS devices. Moreover, the MEMS devices are fabricated simultaneously by using the same device wafer and packaged simultaneously on the same wafer having an interconnect layer. Therefore, the whole fabricating process of the MEMS package is simplified and the cost thereof is reduced compared with those of the conventional MEMS packages.

According to one embodiment of the present disclosure, a MEMS package is provided and includes a wafer, a first device layer, a second device layer, a first cap substrate and a second cap substrate. The wafer has an interconnect layer thereon. The first device layer includes a first MEMS device having a first thickness. The first device layer is disposed on the wafer and bonded to the interconnect layer. The second device layer includes a second MEMS device having a second thickness thinner than the first thickness. The second device layer is laterally spaced apart from the first device layer, disposed on the wafer and bonded to the interconnect layer. The first cap substrate has a first cavity and is bonded to the first device layer, where the first MEMS device corresponds to the first cavity. The second cap substrate has a second cavity, laterally spaced apart from the first cap substrate, and is bonded to the second device layer, where the second MEMS device corresponds to the second cavity.

According to one embodiment of the present disclosure, a method of fabricating a MEMS package is provided and includes the following steps. A cap wafer is provided, and a first cavity and a second cavity are formed in the cap wafer. A device wafer is provided, and a recessed portion is formed in the device wafer. The device wafer is bonded to the cap wafer, where the recessed portion is connected to the second cavity. The device wafer is thinned and patterned to form a first MEMS device and a second MEMS device laterally spaced apart from each other, where the first MEMS device corresponds to the first cavity, and the second MEMS device corresponds to the second cavity. A wafer with an interconnect layer formed thereon is provided, and the device wafer is bonded to the interconnect layer on the wafer. In addition, a portion of the cap wafer and a portion of the device wafer at a scribe line are removed to form a first cap substrate with the first cavity, a second cap substrate with the second cavity, a first device layer with the first MEMS device, and a second device layer with the second MEMS device, where the first MEMS device has a first thickness, and the second MEMS device has a second thickness thinner than the first thickness.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a MEMS package according to one embodiment of the present disclosure.

FIG. 2 is a schematic cross-sectional view of a MEMS package according to another embodiment of the present disclosure.

FIG. 3 is a schematic cross-sectional view of a MEMS package according to further another embodiment of the present disclosure.

FIG. 4, FIG. 5, FIG. 6, FIG. 7 and FIG. 8 are schematic cross-sectional views of some stages of a method of fabricating a MEMS package according to one embodiment of the present disclosure.

FIG. 9 and FIG. 10 are schematic cross-sectional views of some intermediate stages of a method of fabricating a MEMS package according to another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first”, “second”, and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that may vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to MEMS packages and fabrication methods thereof. The MEMS package includes different MEMS devices with different device layer thicknesses. In the MEMS package, a MEMS device requiring a relatively high vacuum has a device layer thickness that is thinner than the device layer thickness of another MEMS device requiring a low vacuum or atmospheric pressure. Moreover, these MEMS devices are fabricated simultaneously by using the same device wafer and packaged simultaneously on the same wafer having an interconnect layer formed thereon. Therefore, the whole fabricating process of the MEMS packages of the present disclosure is simplified. Also, the cost and the time of fabricating the MEMS packages are reduced.

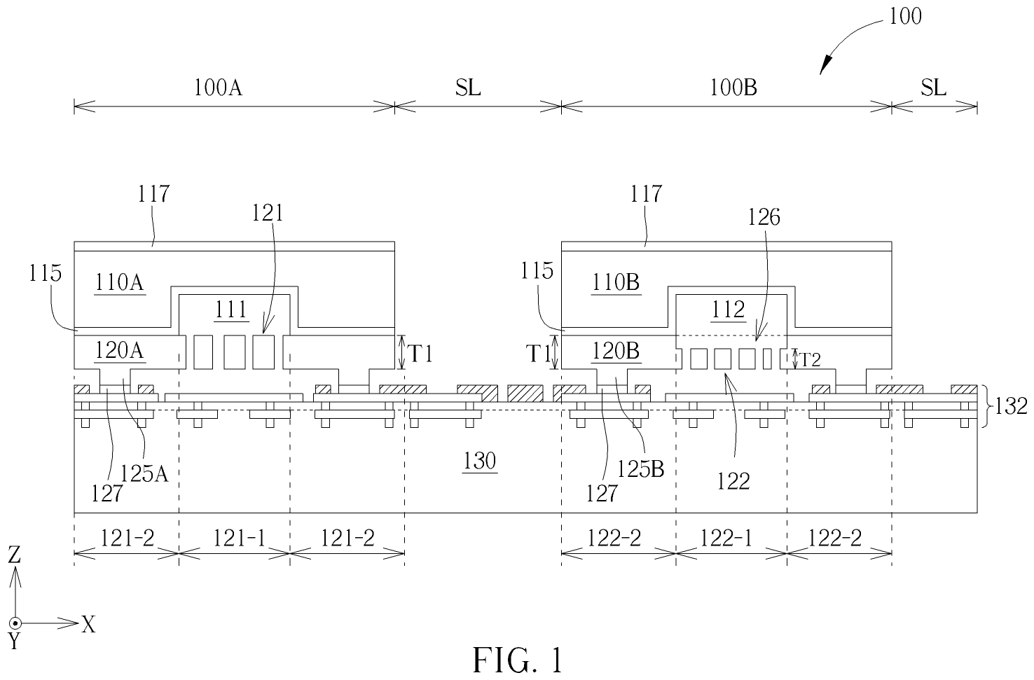

FIG. 1 is a schematic cross-sectional view of a MEMS package 100 according to one embodiment of the present disclosure. The MEMS package 100 includes various MEMS devices with different device layer thicknesses to meet the sensitivity and the performance of each MEMS device. These MEMS devices are laterally spaced from each other and packaged on the same wafer 130. The wafer 130 may include multiple complementary metal oxide semiconductor (CMOS) transistors or other elements formed therein, and an interconnect layer 132 is disposed on the wafer 130. The MEMS package 100 includes a first device layer 120A including a first MEMS device 121 and located in a first MEMS region 100A, and a second device layer 120B including a second MEMS device 122 and located in a second MEMS region 100B. The first MEMS region 100A and the second MEMS region 100B are separated by a scribe line SL. The first device layer 120A and the second device layer 120B are laterally spaced from each other, and both are bonded to the interconnect layer 132 on the wafer 130.

In the MEMS package 100, the first MEMS device 121 and the second MEMS device 122 may require different vacuum levels. In some embodiments, the first MEMS device 121 may be an accelerometer requiring low vacuum or atmospheric pressure, and the second MEMS device 122 may be a gyroscope requiring high vacuum, but not limited thereto. The MEMS structures of the first MEMS device 121 and the second MEMS device 122 are different from each other. Each of the first MEMS device 121 and the second MEMS device 122 may include features such as standoff bumps, trenches, proof masses, etc., and the layout of these features in the first MEMS device 121 is different from that in the second MEMS device 122. In order to make the figure simple and easy to understand, the MEMS structures of the first MEMS device 121 and the second MEMS device 122 are simplified in FIG. 1. For example, the layout of the trenches in first MEMS device 121 is different from the layout of the trenches in the second MEMS device 122.

In addition, the first MEMS device 121 and the second MEMS device 122 have different device layer thicknesses. Referring to FIG. 1, a second device portion 122-1 of the second device layer 120B has a second thickness T2 that is thinner than a first thickness T1 of a first device portion 121-1 of the first device layer 120A. The first MEMS device 121 is located in the first device portion 121-1, and the second MEMS device 122 is located in the second device portion 122-1. Moreover, a second peripheral portion 122-2 of the second device layer 120B has the first thickness T1 that is the same as the first thickness T1 of a first peripheral portion 121-2 of the first device layer 120A.

Furthermore, a first bond seal ring 125A is disposed between the first peripheral portion 121-2 of the first device layer 120A and the wafer 130. The first bond seal ring 125A is bonded to the interconnect layer 132 on the wafer 130 through a bonding material 127. In some embodiments, the composition of the bonding material 127 is metal such as germanium (Ge), so that the first bond seal ring 125A is bonded to a top metal layer of the interconnect layer 132 through the bonding material 127 by eutectic bonding. Also, a second bond seal ring 125B is disposed between the second peripheral portion 122-2 of the second device layer 120B and the wafer 130. The second bond seal ring 125B is also bonded to the top metal layer of the interconnect layer 132 on the wafer 130 through the same bonding material 127 by eutectic bonding. In some embodiments, the first device layer 120A, the first bond seal ring 125A, the first MEMS device 121, the second device layer 120B, the second bond seal ring 125B and the second MEMS device 122 are all formed from the same device wafer. Moreover, the first bond seal ring 125A and the first device layer 120A are connected with each other to be an integral structure. Also, the second bond seal ring 125B and the second device layer 120B are connected with each other to be an integral structure.

Still referring to FIG. 1, the MEMS package 100 further includes a first cap substrate 110A with a first cavity 111, and a second cap substrate 110B with a second cavity 112. The first cap substrate 110A and the second cap substrate 110B are laterally spaced apart from each other. The first cap substrate 110A is bonded to the first device layer 120A, and the second cap substrate 110B is bonded to the second device layer 120B. The first cavity 111 is located directly above and corresponds to the first MEMS device 121. The first device portion 121-1 of the first device layer 120A is located directly below the first cavity 111. The first peripheral portion 121-2 of the first device layer 120A is bonded to the first cap substrate 110A. Both the first device portion 121-1 and the first peripheral portion 121-2 have the first thickness T1.

The second cavity 112 is located directly above and corresponds to the second MEMS device 122. The second device portion 122-1 of the second device layer 120B is located directly below the second cavity 112 and has the second thickness T2. The second peripheral portion 122-2 of the second device layer 120B is bonded to the second cap substrate 110B and has the first thickness T1. Moreover, the second device layer 120B includes a recessed portion 126 located directly above the second MEMS device 122. The recessed portion 126 is produced by the thickness difference between the second peripheral portion 122-2 and the second device portion 122-1 of the second device layer 120B. The recessed portion 126 is connected to the second cavity 112. In some embodiments, the first MEMS device 111 is an accelerometer, and the second MEMS device 122 is a gyroscope. The first cavity 111 has a first pressure, and the second cavity 112 has a second pressure lower than the first pressure.

In addition, the first cap substrate 110A and the second cap substrate 110B are formed from the same cap wafer and have the same composition such as silicon. The first cap substrate 110A is bonded to the first device layer 120A through a bonding layer 115. The second cap substrate 110B is bonded to the second device layer 120B through another bonding layer 115. The bonding layer 115 is disposed between the first device layer 120A and the first cap substrate 110A. The bonding layer 115 is also disposed between the second device layer 120B and the second cap substrate 110B. In some embodiments, the bonding layer 115 is further extended into the first cavity 111 and the second cavity 112 to be conformally disposed on the sidewalls and the bottom surfaces of the first cavity 111 and the second cavity 112. The composition of the bonding layer 115 may be silicon oxide. Moreover, a conductive layer 117 may be disposed on the surfaces of the first cap substrate 110A and the second cap substrate 110B. The conductive layer 117 may be formed without patterning or a patterned conductive layer, which is dependent on the electrical requirements of the conductive layer 117. The conductive layer 117 is electrically coupled to the first MEMS device 121 and the second MEMS device 122 and may be further electrically coupled to the interconnect layer 132. The composition of the conductive layer 117 is, for example, aluminum (Al).

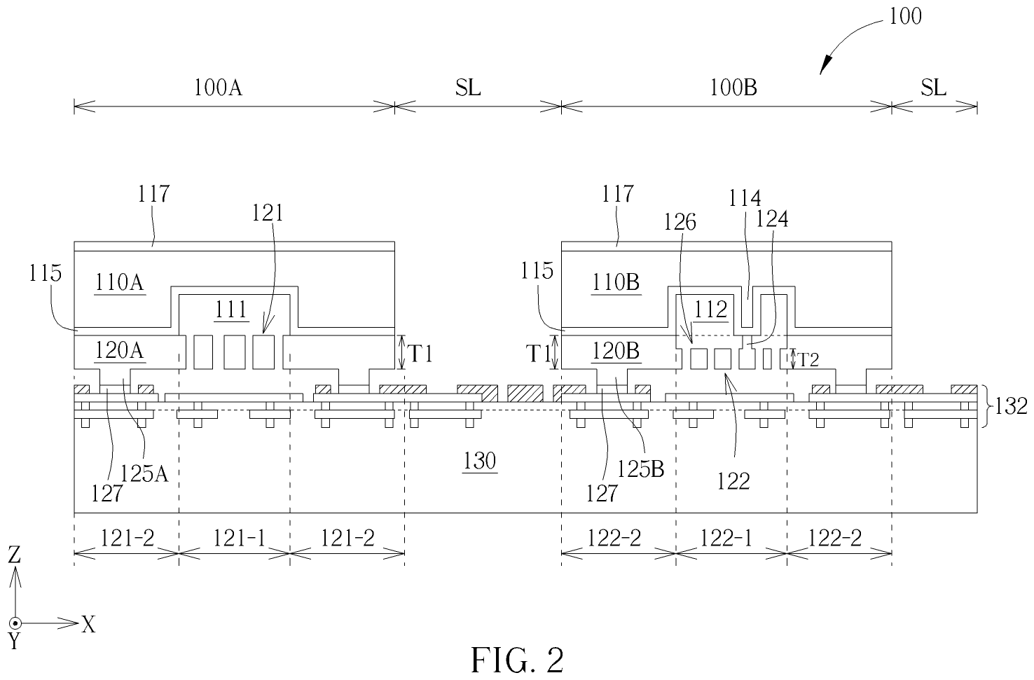

FIG. 2 is a schematic cross-sectional view of a MEMS package 100 according to another embodiment of the present disclosure. In the MEMS package 100 of FIG. 2, the second cap substrate 110B further includes a first stopper 114 disposed in the second cavity 112. The first stopper 114 is connected with the bottom surface of the second cavity 112. In some embodiments, the first stopper 114 and the second cap substrate 110B are formed from the same cap wafer to be an integral structure. The bonding layer 115 is also conformally disposed on the surface and the sidewalls of the first stopper 114. Moreover, the second MEMS layer 120B further includes a second stopper 124 corresponding to the first stopper 114. The second stopper 124 is connected with the top surface of the second MEMS device 122. The second stopper 124, the second MEMS device 122 and the second device layer 120B may be formed from the same device wafer to be an integral structure. In some embodiments, the second stopper 124 may be bonded to the first stopper 114 through the bonding layer 115. The first stopper 114 and the second stopper 124 are located at an anchor end of the second MEMS device 122 for attaching the second MEMS device 122 to the second cap substrate 110B. Moreover, the first stopper 114 and the second stopper 124 support the second device layer 120B during the process of forming the second MEMS device 122. In other embodiments, after the second device layer 120B is bonded with the second cap substrate 110B, the bonding layer 115 between the first stopper 114 and the second stopper 124 may be removed, so that the second stopper 124 is released from the first stopper 114 and not bonded to the first stopper 114. The second stopper 124 may be connected to a proof mass of the second MEMS device 122. The details of the other features in the MEMS package 100 of FIG. 2 may refer to the aforementioned description of FIG. 1, and are not repeated herein.

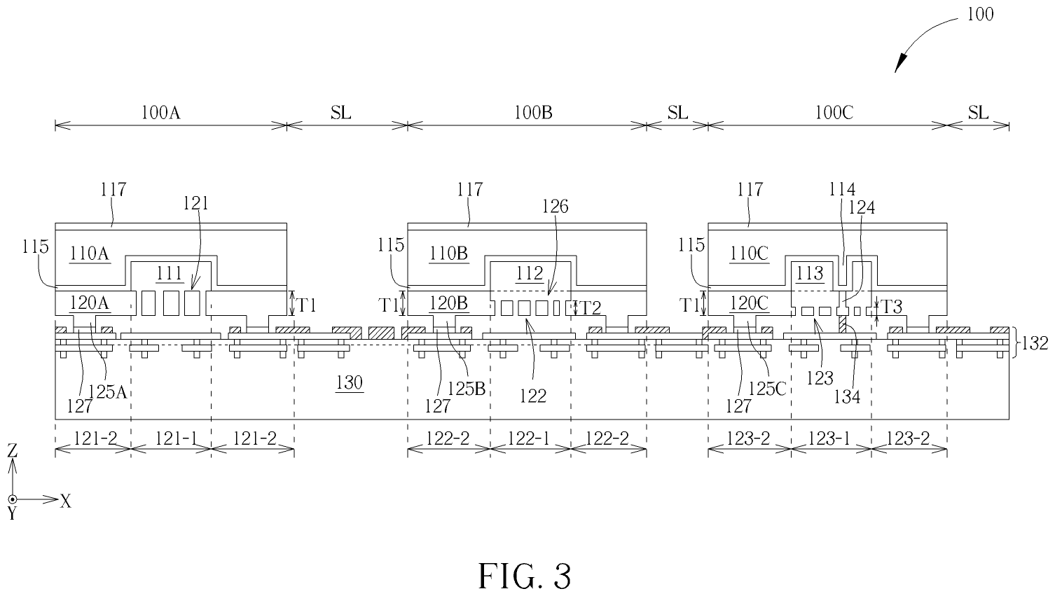

FIG. 3 is a schematic cross-sectional view of a MEMS package 100 according to another embodiment of the present disclosure. The MEMS package 100 of FIG. 3 further includes a third device layer 120C laterally spaced apart from the first device layer 120A and the second device layer 120B. The third device layer 120C includes a third MEMS device 123 and is located in a third MEMS region 100C. The third MEMS region 100C is separated from the second MEMS region 100B by the scribe line SL. The third device layer 120C is also bonded to the interconnect layer 132 on the wafer 130. The third MEMS device 123 may require a vacuum level different from those of the first MEMS device 121 and the second MEMS device 122. For example, the third MEMS device 123 may require a higher vacuum compared with the first MEMS device 121 and the second MEMS device 122. The MEMS structure of the third MEMS device 123 may be different from those of the first MEMS device 121 and the second MEMS device 122. Also, the device layer thickness of the third MEMS device 123 is different from the device layer thicknesses of the second MEMS device 122 and the first MEMS device 121. In one embodiment, the third MEMS device 123 has a third thickness T3 that is thinner than the second thickness T2 of the second MEMS device 122 and much thinner than the first thickness T1 of the first MEMS device 121.

In addition, referring to FIG. 3, a third device portion 123-1 of the third device layer 120C has the third thickness T3. The third MEMS device 123 is located in the third device portion 123-1. A third peripheral portion 123-2 of the third device layer 120C has the first thickness T1 that is the same as the first thickness T1 of the first peripheral portion 121-2 of the first device layer 120A and the second peripheral portion 122-2 of the second device layer 120B. Moreover, a third bond seal ring 125C is disposed between the third peripheral portion 123-2 of the third device layer 120C and the wafer 130. The third bond seal ring 125C is bonded to the interconnect layer 132 on the wafer 130 through the bonding material 127. The third bond seal ring 125C and the third device layer 120C are connected with each other to be an integral structure.

Still referring to FIG. 3, the MEMS package 100 further includes a third cap substrate 110C with a third cavity 113. The third cap substrate 110C is laterally spaced apart from the second cap substrate 110B and the first cap substrate 110A. The third cap substrate 110C is bonded to the third device layer 120C through the bonding layer 115. The bonding layer 115 is also extended into the third cavity 113 to be conformally disposed on the sidewalls and the bottom surface of the third cavity 113. Moreover, the third cavity 113 is located directly above and corresponds to the third MEMS device 123. The third device portion 123-1 of the third device layer 120C is located directly below the third cavity 113 and has the third thickness T3. The third MEMS device 123 is located in the third device portion 123-1. The third peripheral portion 123-2 of the third device layer 120C is bonded to the third cap substrate 110C and has the first thickness T1. There is a recessed portion produced in the third device layer 120C and directly above the third MEMS device 123. The recessed portion of the third device layer 120C is connected to the third cavity 113. In one embodiment, the third cavity 113 has a third pressure different from the first pressure of the first cavity 111 and the second pressure of the second cavity 112. For example, the third pressure of the third cavity 113 may be lower than the second pressure of the second cavity 112 and much lower than the first pressure of the first cavity 111. Moreover, in some embodiments, the conductive layer 117 is also disposed on the surface of the third cap substrate 110C. The conductive layer 117 on the third cap substrate 110C may be formed without patterning or a patterned conductive layer. The conductive layer 117 is electrically coupled to the third MEMS device 123 and may be further electrically coupled to the interconnect layer 132.

In the MEMS package 100 of FIG. 3, the third cap substrate 110C further includes a first stopper 114 disposed in the third cavity 113. The first stopper 114 is connected with the bottom surface of the third cavity 113. The first stopper 114 and the third cap substrate 110C may be formed from the same cap wafer to be an integral structure. The bonding layer 115 is conformally disposed on the surface and the sidewalls of the first stopper 114. Moreover, the third MEMS layer 120C further includes a second stopper 124 corresponding to the first stopper 114 and connected with the top surface of the third MEMS device 123. The second stopper 124 and the third device layer 120C may be formed from the same device wafer to be an integral structure. The second stopper 124 may be bonded to the first stopper 114 through the bonding layer 115. The first stopper 114 and the second stopper 124 are located at an anchor end of the third MEMS device 123.

Furthermore, in the MEMS package 100 of FIG. 3, the wafer 130 further includes a third stopper 134 disposed on the interconnect layer 132 and corresponds to the second stopper 124 and the first stopper 114. The third stopper 134 is in contact with the bottom surface of the third MEMS device 123. In some embodiments, the composition of the third stopper 134 is a dielectric material such as silicon oxide, silicon nitride or a combination thereof. The third stopper 134 supports the third MEMS device 123 after the third MEMS layer 120C is bonded to the interconnect layer 132 on the wafer 130. Moreover, the first stopper 114 and the second stopper 124 support the third MEMS layer 120C during the process of forming the third MEMS device 123. In other embodiments, after the third MEMS layer 120C is bonded with the third cap substrate 110C, the bonding layer 115 between the first stopper 114 and the second stopper 124 may be removed, and the second stopper 124 is released from the first stopper 114. The second stopper 124 may be connected to a proof mass of the third MEMS device 123. The details of the other features in the MEMS package 100 of FIG. 3 may refer to the aforementioned descriptions of FIG. 1, and are not repeated herein.

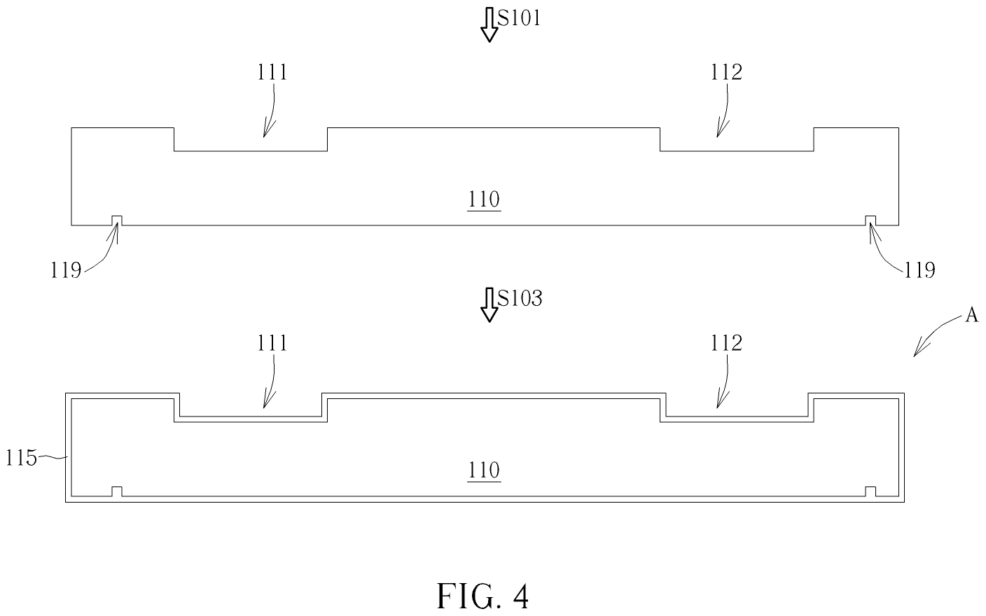

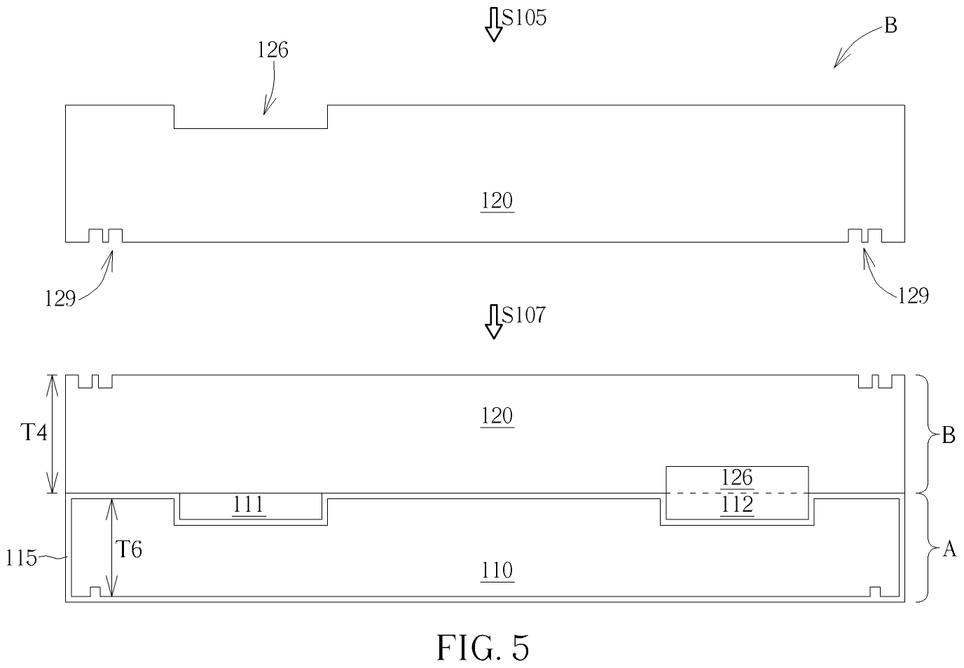

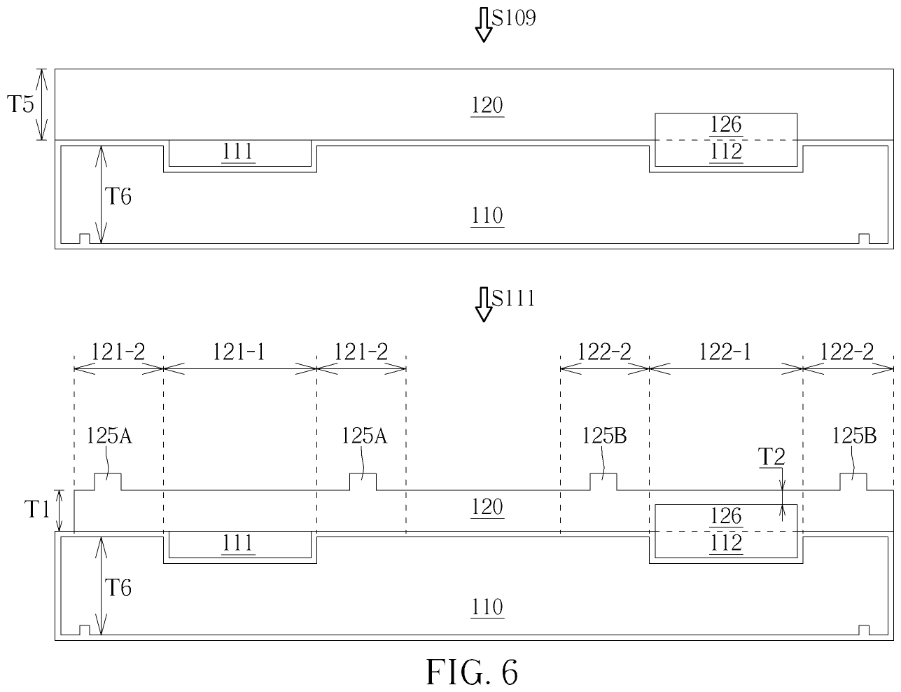

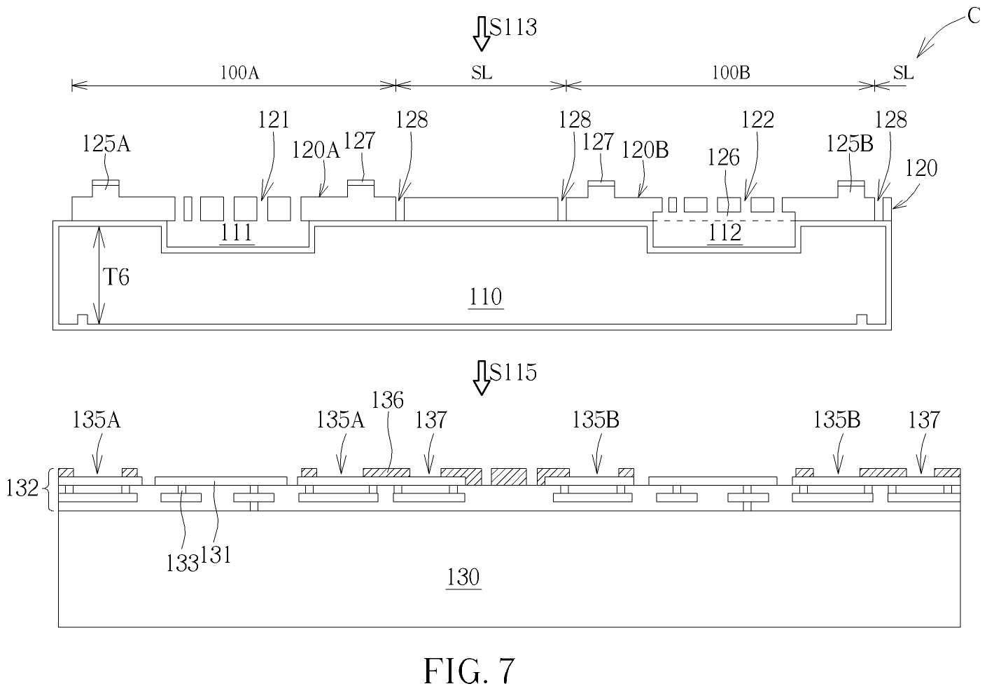

FIG. 4, FIG. 5, FIG. 6, FIG. 7 and FIG. 8 are schematic cross-sectional views of some stages of a method of fabricating a MEMS package 100 according to one embodiment of the present disclosure. Referring to FIG. 4, in step S101, firstly, a cap wafer 110 such as a silicon wafer is provided. Then, a first cavity 111 and a second cavity 112 are formed on the front surface of the cap wafer 110 by an etching process. Moreover, alignment marks 119 are formed on the back surface of the cap wafer 110 by an etching process. Next, in step S103, a bonding layer 115 is conformally formed on the cap wafer 110 and in the first cavity 111 and the second cavity 112 to wrap around the cap wafer 110 to provide a structure A. The bonding layer 115 is formed on the front surface, the sidewalls and the back surface of the cap wafer 110. Moreover, the bonding layer 115 is formed on the sidewalls and the bottom surfaces of the first cavity 111 and the second cavity 112. The composition of the bonding layer 115 is, for example, silicon oxide. The bonding layer 115 may be formed by a thermal oxidation process or a deposition process.

Next, referring to FIG. 5, in step S105, a device wafer 120 such as a silicon wafer is provided. Then, a recessed portion 126 is formed on the front surface of the device wafer 120 by an etching process. Moreover, alignment marks 129 are formed on the back surface of the device wafer 120 by an etching process to provide a structure B. Afterwards, in step S107, the structure B of the device wafer 120 in step S105 is turned upside down and bonded with the structure A of the cap wafer 110 in step S103 through the bonding layer 115 by fusion bonding to cover the first cavity 111 and the second cavity 112. Moreover, the recessed portion 126 of the device wafer 120 is connected to the second cavity 112 of the cap wafer 110. During the process of bonding the device wafer 120 with the cap wafer 110, the alignment marks 119 of the cap wafer 110 are aligned with the alignment marks 129 of the device wafer 120. In step S107, the device wafer 120 has a thickness T4, and the cap wafer 110 has a thickness T6.

Afterwards, referring to FIG. 6, in step S109, the device wafer 120 is thinned by grinding or etching on the back surface to have a thickness T5 that is thinner than the thickness T4. The thickness of the cap wafer 110 is remained as the thickness T6. Next, in step S111, the device wafer 120 is patterned by photolithography and etching processes to form a first bond seal ring 125A, a second bond seal ring 125B and standoff bumps (not shown) on a surface of the device wafer 120. Thereafter, the device wafer 120 has a first thickness T1 that is thinner than the thickness T5. Moreover, the first bond seal ring 125A is formed on a first peripheral portion 121-2 of the thinned device wafer 120. A first device portion 121-1 of the thinned device wafer 120 is located directly above and corresponds to the first cavity 111. The first peripheral portion 121-2 is bonded to the cap substrate 110 and surrounds the first device portion 121-1.

The second bond seal ring 125B is formed on a second peripheral portion 122-2 of the thinned device wafer 120. A second device portion 122-1 of the thinned device wafer 120 is located directly above and corresponds to the recessed portion 126 and the second cavity 112. The second peripheral portion 122-2 is bonded to the cap substrate 110, and surrounds the second device portion 122-1 and recessed portion 126. Moreover, the first device portion 121-1, the first peripheral portion 121-2 and the second peripheral portion 122-2 all have the first thickness T1. The second device portion 122-1 has a second thickness T2 that is thinner than the first thickness T1. In some embodiments, the first thickness T1 is from greater than 30 micrometers (μm) to about 60 μm, and the second thickness T2 is smaller than or equal to about 30 μm, for example, from about 15 μm to about 30 μm, but not limited thereto.

Next, referring to FIG. 7, in step S113, a bonding material 127 such as Ge is formed on the first bond seal ring 125A and the second bond seal ring 125B by deposition and patterning processes. Then, the thinned device wafer 120 is patterned by photolithography and etching processes to simultaneously form a first MEMS device 121 and a second MEMS device 122 laterally spaced apart from each other. The first MEMS device 121 is formed by patterning the first device portion 121-1, and the second MEMS device 122 is formed by patterning the second device portion 122-1. The first MEMS device 121 is directly above and corresponds to the first cavity 111. The second MEMS device 122 is directly above and corresponds to the second cavity 112. The first MEMS device 121 includes multiple trenches connected to the first cavity 111. The second MEMS device 122 includes multiple trenches connected to the recessed portion 126 and the second cavity 112. Moreover, pre-cut lines 128 are formed in the scribe line SL between the first MEMS region 100A and the second MEMS region 100B by patterning the thinned device wafer 120. Thereafter, a first device layer 120A in the first MEMS region 100A is laterally separated from a second device layer 120B in the second MEMS region 100B. A structure C is obtained in step S113, where the device wafer 120 includes the first MEMS device 121 and the second MEMS device 122 and is bonded with the cap wafer 110 having the first cavity 111 and the second cavity 112.

Still referring to FIG. 7, in step S115, a wafer 130 such as a CMOS wafer with an interconnect layer 132 formed thereon is provided. The interconnect layer 132 includes multiple metal layers, multiple IMD layers and multiple vias 133 in the IMD layers to connect two metal layers. The metal layers include a top metal layer 131. Moreover, a passivation layer 136 is deposited on the interconnect layer 132. The composition of the passivation layer 136 is for example silicon oxide, silicon nitride, silicon oxynitride or a combination thereof. The passivation layer 136 is patterned by photolithography and etching processes to form multiple openings. In one embodiment, portions of the top metal layer 131 directly below the MEMS devices are exposed by some openings of the passivation layer 136. A bond ring area 135A and another bond ring area 135B of the interconnect layer 132 are exposed by other openings of the passivation layer 136. The bond ring areas 135A and 135B are provided to be bonded with the first bond seal ring 125A and the second bond seal ring 125B. Moreover, several pad areas 137 of the interconnect layer 132 at the scribe line SL are exposed by some other openings of the passivation layer 136.

Afterwards, referring to FIG. 8, in step S117, the structure C in step S113 of FIG. 7 is turned upside down and bonded with the wafer 130 in step S115 of FIG. 7. The device wafer 120 is bonded to the interconnect layer 132 on the wafer 130 at a first pressure, so that firstly, both the first cavity 111 and the second cavity 112 have the first pressure. The bonding material 127 on the first bond seal ring 125A and the second bond seal ring 125B is bonded to the bond ring areas 135A and 135B of the interconnect layer 132 by eutectic bonding. Then, the cap wafer 110 is thinned on the back surface by backside grinding or dry etching to have a thickness T7 that is thinner than the thickness T6 in step S113 of FIG. 7. The bonding layer 115 on the back surface of the cap wafer 110 is also removed.

Next, still referring to FIG. 8, in step S119, in one embodiment, a conductive layer 117 is formed by depositing a metal layer such as an aluminum layer on the back surface of the thinned cap wafer 110. In this embodiment, the conductive layer 117 is formed without patterning. In another embodiment, the aforementioned metal layer is patterned by photolithography and etching processes to form a conductive layer 117. In this embodiment, the conductive layer 117 is a patterned conductive layer. Afterwards, a portion of the cap wafer 110 and a portion of the device wafer 120 at the scribe line SL between the pre-cut lines 128 are removed by a sawing process, so that the pads on the interconnect layer 132 at the scribe line SL are exposed. Thereafter, a first cap substrate 110A with the first cavity 111 and a second cap substrate 110B with the second cavity 112 are formed and laterally spaced from each other. Also, the first device layer 120A with the first MEMS device 121 and the second device layer 120B with the second MEMS device 122 are laterally spaced from each other. In addition, the pressure in the first cavity 111 is maintained at the first pressure. The pressure in the second cavity 112 is reduced from the first pressure to a second pressure through a vent hole in the second cap substrate 110B by vacuum pumping or other methods to reduce the pressure in the second cavity 112. Therefore, the first cavity 111 has the first pressure, and the second cavity 112 has the second pressure lower than the first pressure. In some embodiments, the first MEMS device 121 is, for example, an accelerometer, and the second MEMS device 122 is, for example, a gyroscope, but not limited thereto. The first MEMS device 121 and the second MEMS device 122 are fabricated and packaged simultaneously on the same wafer 130 to complete the MEMS package 100 of FIG. 1. Moreover, the first MEMS device 121 has the first thickness T1, and the second MEMS device 122 has the second thickness T2 that is thinner than the first thickness T1.

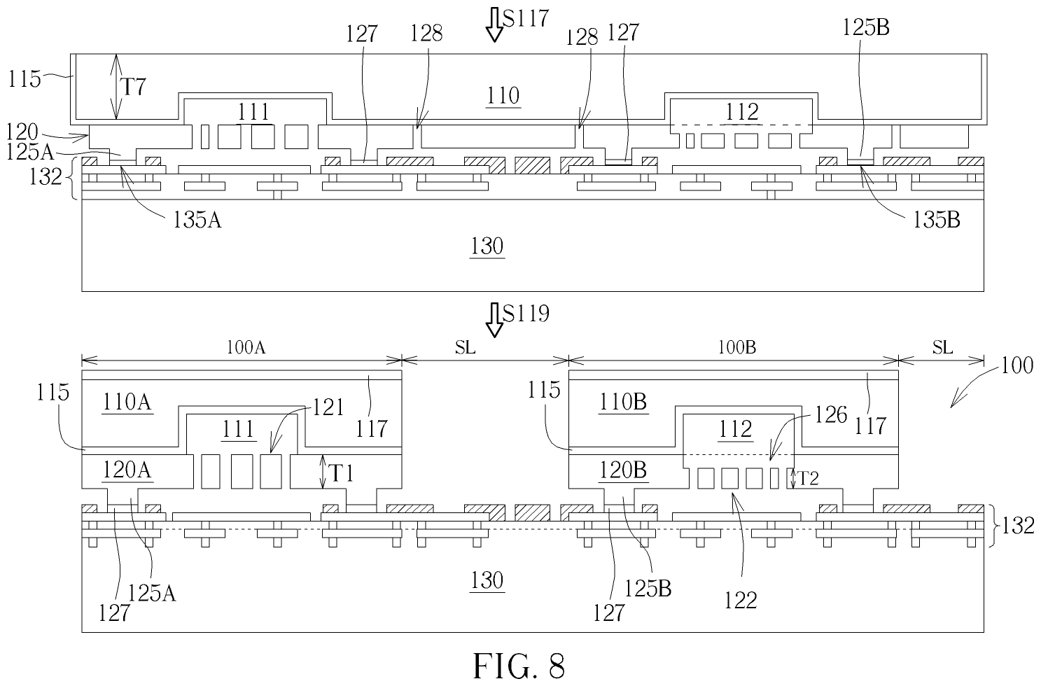

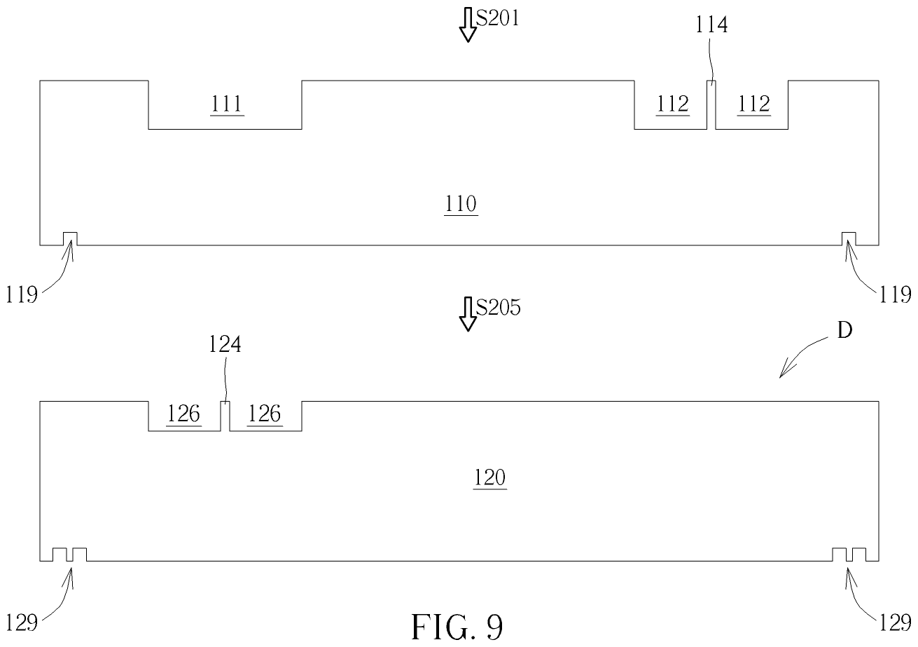

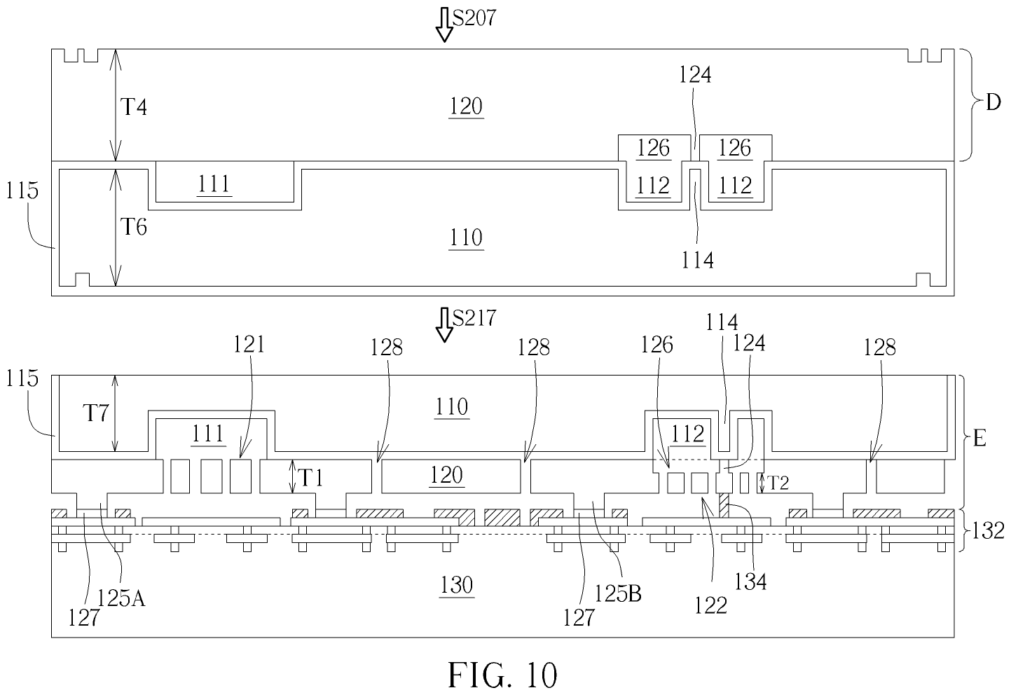

FIG. 9 and FIG. 10 are schematic cross-sectional views of intermediate stages of a method of fabricating a MEMS package 100 according to another embodiment of the present disclosure. Referring to FIG. 9, in step S201, a cap wafer 110 such as a silicon wafer is provided. Then, a first cavity 111, a second cavity 112 and a first stopper 114 are simultaneously formed by an etching process on the front surface of the cap wafer 110. The first stopper 114 is formed in the second cavity 112 and connected with the bottom surface of the second cavity 112. Thereafter, the aforementioned process in step S103 is performed on the cap wafer 110 in step S201 to form a bonding layer 115. The bonding layer 115 is formed to wrap around the cap wafer 110 and is conformally deposited in the first cavity 111 and the second cavity 112, and on the first stopper 114.

Next, stilling referring to FIG. 9, in step S205, a device wafer 120 such as a silicon wafer is provided. Then, a recessed portion 126 and a second stopper 124 are simultaneously formed by an etching process on the front surface of the device wafer 120 to provide a structure D. The second stopper 124 is formed in the recessed portion 126 and connected with the bottom surface of the recessed portion 126.

Afterwards, referring to FIG. 10, in step S207, the structure D of the device wafer 120 in step S205 is turned upside down and bonded with the cap wafer 110 through the bonding layer 115 by fusion bonding to cover the first cavity 111 and the second cavity 112. After the device wafer 120 is bonded to the cap wafer 110, the second stopper 124 is also bonded with the first stopper 114 through the bonding layer 115. In step S207, the device wafer 120 has the thickness T4, and the cap wafer 110 has the thickness T6.

Thereafter, the aforementioned processes in steps S109, S111, and S113 are performed on the device wafer 120 to form the first bond seal ring 125A, the second bond seal ring 125B, the first MEMS device 121, the second MEMS device 122, the bonding material 127, the pre-cut lines 128, the first device layer 120A and the second device layer 120B. In addition, referring to the aforementioned step S115 of FIG. 7, the wafer 130 such as a CMOS wafer with the interconnect layer 132 formed thereon is provided. Furthermore, in this embodiment, a third stopper 134 is formed on the interconnect layer 132 by deposition and etching processes. The composition of the third stopper 134 may be silicon oxide, silicon nitride, silicon oxynitride or a combination thereof.

Next, still referring to FIG. 10, in step S217, a structure E of the device wafer 120 having the aforementioned features and bonded with the cap wafer 110 is then bonded to the interconnect layer 132 on the wafer 130. The bonding material 127 on the first bond seal ring 125A and the second bond seal ring 125B is bonded to the bond ring areas 135A and 135B of the interconnect layer 132 by eutectic bonding. After the device wafer 120 is bonded to the interconnect layer 132 on the wafer 130, the third stopper 134 is in contact with the bottom surface of the second MEMS device 122 and corresponds to the second stopper 124 and the first stopper 114. In step S217, firstly, both the first cavity 111 and the second cavity 112 have the first pressure. Then, the cap wafer 110 is thinned on the back surface by backside grinding or dry etching to have the thickness T7 that is thinner than the thickness T6 of the cap wafer 110 in step S207. The bonding layer 115 on the back surface of the cap wafer 110 is also removed.

Afterwards, the aforementioned process of step S119 is performed on the cap wafer 110 and the device wafer 120 to form the conductive layer 117, the first cap substrate 110A with the first cavity 111, the second cap substrate 110B with the second cavity 112, the first device layer 120A with the first MEMS device 121, and the second device layer 120B with the second MEMS device 122 to complete a MEMS package. In the MEMS package, the first MEMS device 121 has the first thickness T1, and the second MEMS device 122 has the second thickness T2 that is thinner than the first thickness T1. Moreover, the pressure in the first cavity 111 is maintained at the first pressure. The pressure in the second cavity 112 is reduced from the first pressure to the second pressure. In addition, the MEMS packages 100 of FIG. 2 and FIG. 3, or the other MEMS packages requiring different device layer thicknesses may be fabricated by using the aforementioned steps of FIG. 4 to FIG. 8, and the aforementioned steps of FIG. 9 and FIG. 10.

According to the embodiments of the present disclosure, the MEMS package includes different MEMS devices with different device layer thicknesses, and these MEMS devices are fabricated and packaged simultaneously on the same wafer. Therefore, the whole fabricating process of the MEMS packages of the present disclosure is simplified compared with the conventional MEMS packages. Furthermore, the MEMS packages of the present disclosure do not require individual wire bonding, thereby reducing the parasitic effect.

Moreover, in the embodiments of the present disclosure, the device layer thicknesses of different MEMS devices are controlled by etching the same device wafer without additional device wafer. Therefore, the cost and the time of fabricating the MEMS packages are reduced. Furthermore, the device layer thicknesses of the different MEMS devices are precisely controlled, thereby satisfying the sensitivities and the performances of the different MEMS devices. In addition, the MEMS packages of the present disclosure are suitable for 1-axis, 2-axis, 3-axis and 6-axis inertial measurement unit (IMU) and other MEMS devices requiring different device layer thicknesses.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-electro-mechanical system (MEMS) package, comprising:
a wafer with an interconnect layer;
a first device layer comprising a first MEMS device having a first thickness, disposed on the wafer and bonded to the interconnect layer;
a second device layer comprising a second MEMS device having a second thickness thinner than the first thickness, laterally spaced apart from the first device layer, disposed on the wafer and bonded to the interconnect layer;
a first cap substrate with a first cavity, bonded to the first device layer, wherein the first MEMS device corresponds to the first cavity; and
a second cap substrate with a second cavity, laterally spaced apart from the first cap substrate, and bonded to the second device layer, wherein the second MEMS device corresponds to the second cavity.

2. The MEMS package of claim 1, wherein the second device layer comprises a second device portion and a second peripheral portion, the second device portion is located directly below the second cavity and has the second thickness, and the second peripheral portion is bonded to the second cap substrate and has the first thickness.

3. The MEMS package of claim 1, wherein the first device layer comprises a first device portion and a first peripheral portion, the first device portion is located directly below the first cavity, the first peripheral portion is bonded to the first cap substrate, and both the first device portion and the first peripheral portion have the first thickness.

4. The MEMS package of claim 1, wherein the second device layer comprises a recessed portion connected to the second cavity.

5. The MEMS package of claim 1, wherein the first MEMS device comprises an accelerometer, the second MEMS device comprises a gyroscope, the first cavity has a first pressure, and the second cavity has a second pressure lower than the first pressure.

6. The MEMS package of claim 1, further comprising:
a first bond seal ring, disposed between the first device layer and the wafer, and bonded to the interconnect layer; and
a second bond seal ring, disposed between the second device layer and the wafer, and bonded to the interconnect layer.

7. The MEMS package of claim 1, wherein the second cap substrate comprises a first stopper disposed in the second cavity, and the second MEMS layer comprises a second stopper corresponding to the first stopper.

8. The MEMS package of claim 7, wherein the first stopper is connected with a bottom surface of the second cavity, the second stopper is connected with a top surface of the second MEMS device and bonded to the first stopper.

9. The MEMS package of claim 7, wherein the wafer comprises a third stopper disposed on the interconnect layer, the third stopper corresponds to the second stopper and is in contact with a bottom surface of the second MEMS device.

10. The MEMS package of claim 1, further comprising:
a third device layer comprising a third MEMS device having a third thickness different from the first thickness and the second thickness, laterally spaced apart from the first device layer and the second device layer, disposed on the wafer and bonded to the interconnect layer; and
a third cap substrate with a third cavity, laterally spaced apart from the first cap substrate and the second cap substrate, and bonded to the third device layer, wherein the third MEMS device corresponds to the third cavity,
wherein the first cavity has a first pressure, the second cavity has a second pressure lower than the first pressure, and the third cavity has a third pressure different from the first pressure and the second pressure.

11. A method of fabricating a micro-electro-mechanical system (MEMS) package, comprising:
providing a cap wafer;
forming a first cavity and a second cavity in the cap wafer;
providing a device wafer;
forming a recessed portion in the device wafer;
bonding the device wafer to the cap wafer, wherein the recessed portion is connected to the second cavity;
thinning the device wafer;
patterning the device wafer to form a first MEMS device and a second MEMS device laterally spaced apart from each other, wherein the first MEMS device corresponds to the first cavity, and the second MEMS device corresponds to the second cavity;
providing a wafer with an interconnect layer formed thereon;
bonding the device wafer to the interconnect layer on the wafer; and
removing a portion of the cap wafer and a portion of the device wafer at a scribe line to form a first cap substrate with the first cavity, a second cap substrate with the second cavity, a first device layer with the first MEMS device, and a second device layer with the second MEMS device,
wherein the first MEMS device has a first thickness, and the second MEMS device has a second thickness thinner than the first thickness.

12. The method of claim 11, further comprising etching the device wafer to form a first bond seal ring and a second bond seal ring after thinning the device wafer, wherein a first device portion of the device wafer corresponding to the first cavity has the first thickness, and a second device portion of the device wafer corresponding to the recessed portion and the second cavity has the second thickness.

13. The method of claim 12, wherein the first MEMS device is formed by patterning the first device portion of the device wafer, and the second MEMS device is formed by patterning the second device portion of the device wafer.

14. The method of claim 12, wherein a second peripheral portion of the device wafer is bonded to the cap substrate, surrounds the second device portion and recessed portion, and has the first thickness.

15. The method of claim 12, wherein a first peripheral portion of the device wafer is bonded to the cap substrate, surrounds the first device portion, and has the first thickness.

16. The method of claim 11, wherein forming the second cavity in the cap wafer further comprises forming a first stopper in the second cavity and connected with a bottom surface of the second cavity, and the first cavity, the second cavity and the first stopper are formed simultaneously by etching the cap wafer.

17. The method of claim 16, wherein forming the recessed region in the device wafer further comprises forming a second stopper in the recessed portion and connected with a bottom surface of the recessed portion, and the recessed portion and the second stopper are formed simultaneously by etching the device wafer.

18. The method of claim 17, wherein after bonding the device wafer to the cap wafer, the second stopper is bonded with the first stopper.

19. The method of claim 17, further comprising forming a third stopper on the interconnect layer, wherein after bonding the device wafer to the interconnect layer on the wafer, the third stopper is in contact with a bottom surface of the second MEMS device and corresponds to the second stopper and the first stopper.

20. The method of claim 11, wherein the first MEMS device comprises an accelerometer, the second MEMS device comprises a gyroscope, the first cavity has a first pressure, and the second cavity has a second pressure lower than the first pressure.
